(19) United States
(12) Patent Application Publication
(10) Pub. No.: US 2021/0225856 A1
(43) Pub. Date: Jul. 22, 2021

(54) CELL STRUCTURE AND OPERATION OF SELF-ALIGNED PMOS FLASH MEMORY

(71) Applicant: Cloudwalk Technology Corp., Santa Clara, CA (US)

(72) Inventor: Xi ZHOU, Santa Clara (US)

(73) Assignee: Cloudwalk Technology Corp., Santa Clara, CA (US)

(21) Appl. No.: 16/745,364

(22) Filed: Jan. 17, 2020

(51) Int. Cl. H01L 27/11521; G11C 16/10; G11C 16/04; G11C 16/24; G11C 16/08; H01L 29/788

(52) U.S. Cl. CPC H01L 27/11521; G11C 16/10; G11C 16/045; G11C 2216/10; G11C 16/08; H01L 29/7883; G11C 16/24

(57) ABSTRACT

Techniques described herein generally relate to the fabrication of a P-type metal-oxide-semiconductor (PMOS) flash memory cell in a semiconductor substrate. The PMOS flash memory cell may include a P-substrate layer formed above the semiconductor substrate, a N-well formed in the P-substrate layer, a floating-gate formed above the N-well. Further, the PMOS memory cell may include a control-gate formed above the floating-gate, a select-gate formed above the N-well and extending over at least a portion over the floating-gate, a P-source formed in the N-well, and a P-Drain. The P-source is formed adjacent to the floating-gate, and the P-drain is formed adjacent to the select-gate.

### BACKGROUND

Unless otherwise indicated herein, the approaches described in this section are not prior art to the claims in this application and are not admitted to be prior art by inclusion in this section.

Non-volatile memory devices are currently in wide use in electronic components that require the retention of information when electrical power is terminated. Non-volatile memory devices may include read only memory (ROM), programmable read only memory (PROM), erasable programmable read only memory (EPROM) and electrically erasable programmable read only memory (EEPROM) devices. EEPROM devices differ from other non-volatile memory devices in that they can be electrically programmed and erased. Flash EEPROM devices are similar to EEPROM devices in that memory cells can be programmed and erased electrically. However, flash EEPROM devices enable the erasing of all memory cells in the device using a single electrical current pulse.

Typically, an EEPROM device includes a floating-gate electrode upon which electrical charge is stored. In a flash EEPROM device, electrons are transferred to a floating-gate electrode through a dielectric layer overlying the channel region of the transistor. The electron transfer is initiated by either hot electron injection or Fowler-Nordheim (F-N) tunnelling.

Many flash memory manufacturers chose a thin oxide floating-gate process to make an electrically erasable PROM. As seen in a prior art FIG. 1A, a basic cell may include a floating gate (FG) isolated in silicon dioxide, and a control-gate (CG) which is stacked above it. The storage transistor is programmed by Hot Carrier Injection of electrons through a gate oxide layer between the gate and the N-drain of the transistor.

Another prior art may be shown in FIG. 1B, in which a cell may have a split gate structure. The split gate cell may have a select gate (SG) in addition to a FG and a CG. One disadvantage of this design is that the cell size is increased and the manufacture of the cell suffers from alignment sensitivity.

### SUMMARY

Techniques described herein generally relate to the fabrication of a P-type metal-oxide-semiconductor (PMOS). In one or more embodiments of the present disclosure, a PMOS flash memory cell may be fabricated in a semiconductor substrate. The PMOS flash memory cell may include a P-substrate layer formed above the semiconductor substrate, a N-well formed in the P-substrate layer, a floating-gate formed above the N-well. Further, the PMOS memory cell may include a control-gate formed above the floating-gate, a select-gate formed above the N-well and extending over at least a portion over the floating-gate, a P-source formed in the N-well, and a P-Drain. The P-source is formed adjacent to the floating-gate, and the P-drain is formed adjacent to the select-gate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1A shows a first prior-art flash memory cell;

FIG. 1B shows a second prior-art flash memory cell;

FIG. 2A shows a semiconductor structure that can be used to construct a P-type metal-oxide-semiconductor (PMOS) flash memory cell;

FIG. 2B shows a PMOS flash memory that is construct using an array of PMOS flash memory cells;

FIG. 3 shows how electrons may be injected into the floating-gate of a PMOS flash memory cell during a program-operation;

FIG. 4A shows a program-operation performed on a specific PMOS flash memory cell;

FIG. 4B shows an inhibiting operation performed on a PMOS flash memory cell that is connected with the same word-line as another memory cell that is being programmed;

FIG. 4C shows an inhibiting operation performed on a PMOS flash memory cell that is connected with the same bit-line as another memory cell that is undergoing a program-operation;

FIG. 4D shows the overall voltage applications to a PMOS flash memory when one memory cell is being programmed;

FIG. 5A shows a read-operation performed on a specific PMOS flash memory cell;

FIG. 5B shows an inhibiting operation performed on a PMOS flash memory cell that is connected with the same word-line as another memory cell that is being read;

FIG. 5C shows an inhibiting operation performed on a PMOS flash memory cell that is connected with the same bit-line as another memory cell that is being read;

FIG. 5D shows the overall voltage applications to a PMOS flash memory when one memory cell is being read;

FIG. 6A shows an erase-operation performed on a specific PMOS flash memory cell;

FIG. 6B shows the overall voltage applications to a PMOS flash memory when during an erase-operation; and

FIG. 7 shows a flow diagram of an illustrative embodiment of a process for programming and reading a P-type metal-oxide-semiconductor (PMOS) flash memory cell, all arranged in accordance to at least some embodiments of the present disclosure.

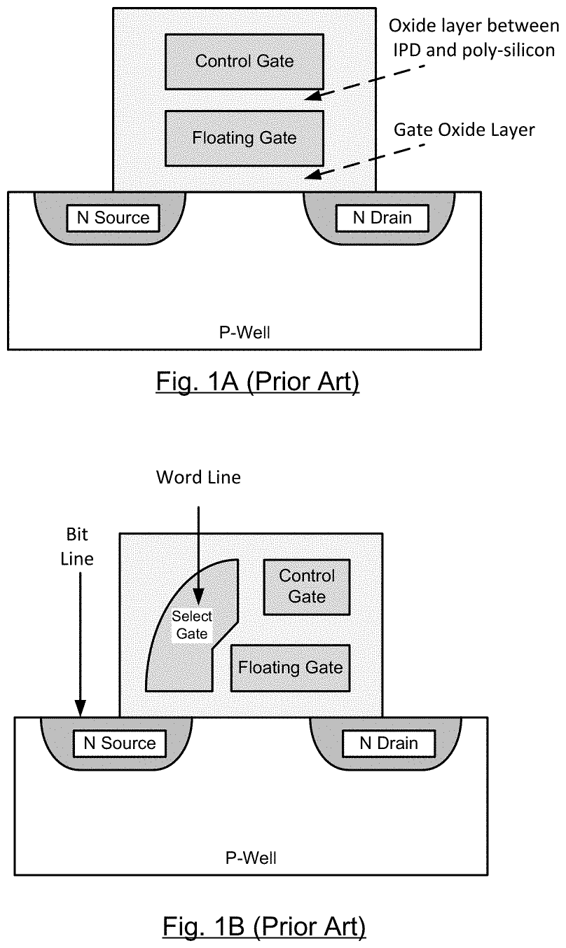

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated herein.

Throughout the disclosure, the term “semiconductor structure” may broadly refer to a physical structure constructed based on a semiconductor fabrication process. For example, a fabrication process may be a multiple-step sequence of photographic and chemical-processing operations. During the fabrication process, different electronic components may gradually be created on a semiconductor wafer using various depositions and etching operations. The fabrication process may deposit a layer of material on top of other materials, or etch/wash away material from the semiconductor structure. Throughout the disclosure, when a first layer of material is deposited “above” a second layer of material, the first layer of material may either be directly on the top of the second layer, or there might be additional material in between the first and the second layers. In other words, after the second layer of material is fabricated, additional material may be deposited on the top of the second layer before the first layer of material being deposited. Further, the term “top”, “bottom”, “above”, “below”, “up”, or “down” may be relative to one surface of a horizontally-placed silicon wafer.

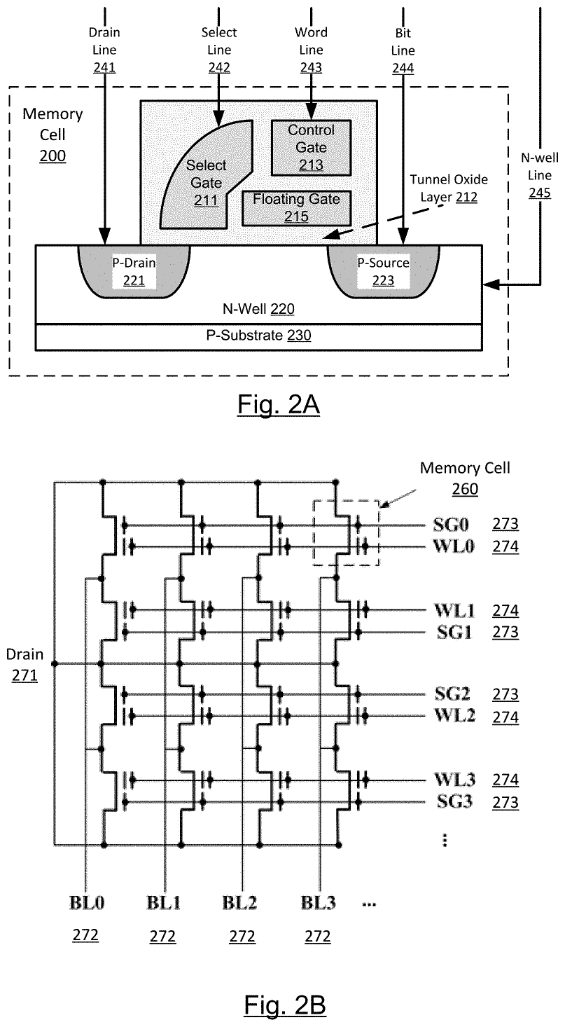

FIG. 2A shows a semiconductor structure that can be used to construct a P-type metal-oxide-semiconductor (PMOS) flash memory cell, in accordance with at least some embodiments of the present disclosure. In FIG. 2A, a memory cell 200 may be a semiconductor structure constructed above a substrate surface of a silicon wafer (not shown in FIG. 2A). The memory cell 200 may have a P-substrate layer 230 formed above the substrate surface of the silicon wafer, and am N-well 220 structure formed above or within the P-substrate layer 230. A P-Drain region 221 and a P-Source region 223 may be formed in the N-well 220 using ion-implantation techniques. The PMOS flash memory cell may be formed based on the P-Type drain region 221 and source region 223.

In some embodiments, a tunnel-oxide-layer 212 may be formed above the N-Well layer 220. The tunnel-oxide-layer 212 may preferably have a thickness of 40-120 angstroms and can be formed using thermal oxidation or by chemical vapor deposition (CVD) operations. Above the tunnel-oxide-layer 212, a floating-gate 215 may be constructed by performing depositing and etching operations above the tunnel-oxide layer 212. The floating gate 215 may be constructed based on polysilicon and oxide material.

In some embodiments, a select-gate 211 may be formed above the tunnel-oxide-layer 212 and overlap at least a portion of the floating-gate 215. Specifically, the select-gate 211 may overlap a portion of the floating-gate 215 by extending above and over an edge of the floating-gate 215. To construct such a select-gate 211, a first polysilicon layer may be deposited above the tunnel-oxide-layer 212. Afterward, a second polysilicon layer may then be patterned and etched to form the overlapping portion of the select-gate 211.

In some embodiments, the select-gate 221 may be formed adjacent to the P-Drain region 221, and the floating-gate 215 may be formed adjacent to the P-Source region 223. Further, a control-gate 213 may be constructed above the floating-gate 215 and on the side of the overlapping portion of the select-gate 211. Thus, the floating-gate 215 may be partially covered by the select-gate 211, and partially covered by the control-gate 213. Afterward, additional oxide layer may cover the select-gate 211 and control-gate 213. Thus, the select-gate 211, the control-gate 213, and the floating-gate 215, which may be separated by oxide material, may form the split gate structure for the PMOS flash memory cell.

In some embodiments, multiple metal lines may connect the various gates and regions of the memory cell 200. Specifically, the P-Drain region 221 may be connected with a drain-line (DL) 241, the select-gate 211 may be connected with a select-line (SG) 242, the control-gate 213 may be connected with a word-line (WL) 243, the P-Source region 223 may be connected with a bit-line (BL) 244, and the N-Well 220 may be connected with a N-Well line 245. Various electronic voltages may be applied to these metal lines during the different memory cell operations, as described below.

FIG. 2B shows a PMOS flash memory that is construct using an array of PMOS flash memory cells, in accordance with at least some embodiments of the present disclosure. In FIG. 2B, the PMOS flash memory may be formed using multiple memory cells 260 (each of which may be constructed based on the memory ell 200 of FIG. 2A) that are connected into a grid/array by various drain-lines 271, bit-lines 272, select-lines 273, and word-lines 274. Specifically, multiple memory cells 260 may be connected by a corresponding select-line and a corresponding word-line into a “row”, and multiple memory cells 260 may be connected by a corresponding bit-line into a “column.” Further, a drain-line 271 may connect all of the memory cells 260 in the PMOS flash memory.

In some embodiments, each memory cell 260 in the PMOS flash memory may be located in a specific row and a specific column, and a memory controller for the PMOS flash memory may perform a program-operation or a read-operation on a specific memory cell by applying different voltages to the bit-line, select-line, word-line, and drain-line that are connected to the specific memory cell. During a program-operation, data may be stored into a PMOS memory cell. During a read-operation, data stored in a PMOS memory cell may be read/accessed. The memory controller may erase all the memory cells in the PMOS flash memory via a single erase-operation.

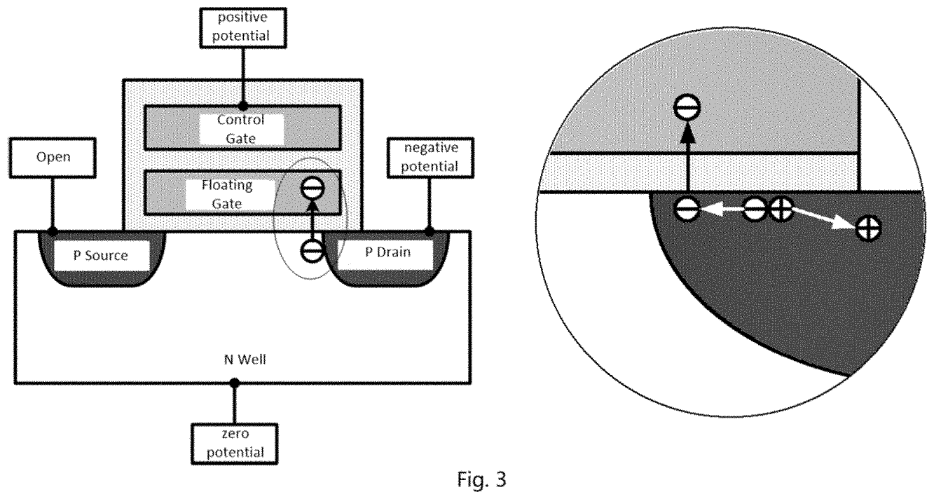

FIG. 3 shows how electrons may be injected into the floating-gate of a PMOS flash memory cell during a program-operation, in accordance with at least some embodiments of the present disclosure. For N-type MOS cells, the program-operation may be based on the principle of channel hot electron injection (CHEI). However, even if the N-type MOS may have higher injection efficiency with the usage of source injection technology (Source Side Injection, SSI), the programming current may still be in the order of micro-ampere (uA). In comparison, for a P-type MOS, the programming current by Band-to-Band Hot Electron (BBHE) may be in the order of nano-ampere (nA). As shown in FIG. 3, the low current applied in the P-Drain region may be sufficient to allow electrons to enter into the floating-gate, thereby allowing a programming-operation to be successfully completed.

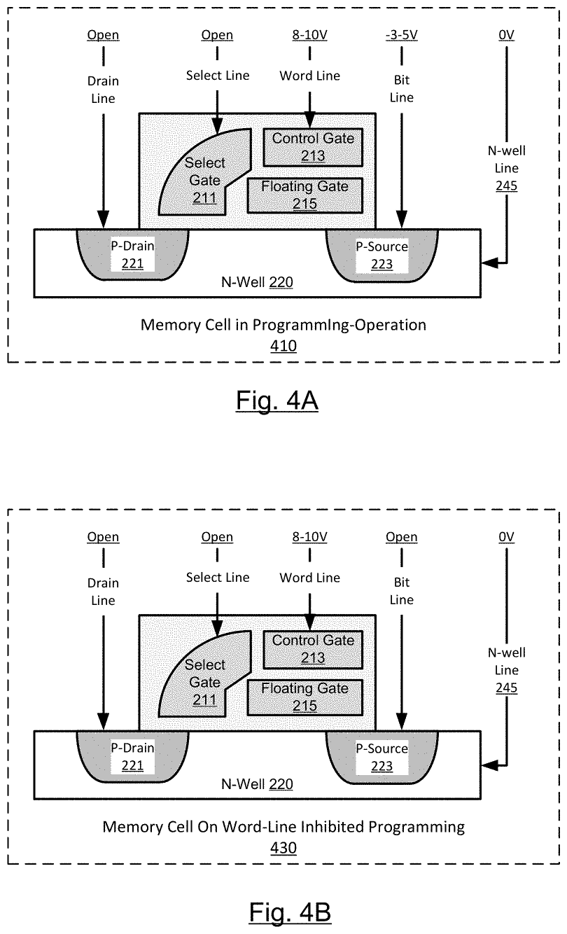

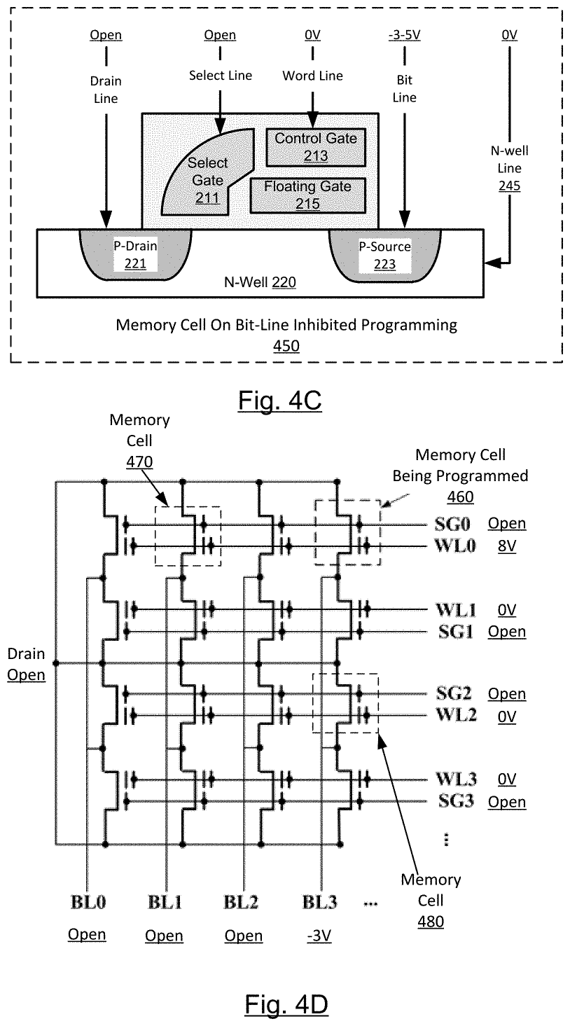

FIG. 4A shows a program-operation performed on a specific PMOS flash memory cell, in accordance with at least some embodiments of the present disclosure. In FIG. 4A, the memory cell 410 may be undergoing a program-operation for data storage. A memory controller (not shown in FIG. 4A), which may control the overall storage operations of the whole PMOS flash memory, may apply different voltages to the various lines that are connected to this specific memory cell 410.

In some embodiments, the memory controller may open the P-Drain region 221 and the select-gate 211 by not intentionally applying any voltage to the drain-line and the select-line connected to them, respectively. The memory controller may apply a zero-voltage (e.g., substantially 0V) to the N-Well 220, and a negative-voltage (e.g., “minus 3 volt”, or −3V) to the P-Source region 223 via the bit-line. In some instances, the “negative-voltage” may be “negative” in comparison to the voltage applied to the word-line, and may have a range of −3V to 5V.

In some embodiments, the memory controller may apply a positive-voltage (e.g., ranging between 8V to 10V) to the control-gate 213 via its connected word-line. As long as the voltage difference between the word-line and bit-line is at least 11V, the surface of the overlapping region of P-Source region 223 and the floating gate 215 may be depleted and have silicon band bending occurring. As a result, the electrons in the valence band in the depletion region may reach the conduction band through the band-band tunneling effect, and become free electrons. Free electron holes are therefore left in the valence band. The electron holes in the valence band are collected by P-Source region 223. Under the action of CG high voltage, the electrons in the conduction band pass through the oxide layer barrier by tunnelling, and reach the floating-gate 215, as shown in FIG. 3. Since the floating-gate 215 is enclosed by dielectric layer, the electrons arriving at the floating-gate are bound in the potential well, so that the threshold voltage of MOS cell is changed.

Once all the above voltages are applied, the memory cell 410 may be programmed/written with storage data, which may then be subsequently accessed. As for cells adjacent to this memory cell 410, no electron enters their respective floating-gates, no matter whether their P-Source region is open or the control gate is applied with 0 V.

FIG. 4B shows an inhibiting operation performed on a PMOS flash memory cell that is connected with the same word-line as another memory cell that is being programmed, in accordance with at least some embodiments of the present disclosure. In FIG. 4B, the memory cell 430 may be a memory cell inhibited from being programmed, when another memory cell (similar to the memory cell 410 of FIG. 4A) that is connected with memory cell 430 via the same word-line and is undergoing a program-operation. In this case, similar to memory cell 410 of FIG. 4A, the memory controller may open the drain-line and the select-line (i.e., open the P-Drain region 221 and select-gate 211 of the memory cell 430). The memory controller may apply a zero-voltage (substantially 0V) to the N-Well 220. Since the memory cell 410 and the memory cell 430 are sharing a common word-line, the same positive-voltage (8V-10V) that is applied to the word-line of the memory cell 410 is also applied to the word-line of the memory cell 430.

In some embodiments, to inhibit/prevent data from being programmed/written to the memory cell 430, the memory controller may open the bit-line that is connected to the memory cell 430. In other words, by opening the bit-line and the P-Source region 223, the memory cell 430, which is sharing a word-line with a memory cell undergoing programming, would not be programmed.

FIG. 4C shows an inhibiting operation performed on a PMOS flash memory cell that is connected with the same bit-line as another memory cell that is undergoing a program-operation, in accordance with at least some embodiments of the present disclosure. In FIG. 4C, the memory cell 450 may be a memory cell inhibited from being programmed, when another memory cell (similar to the memory cell 410 of FIG. 4A) that is connected with memory cell 430 via the same bit-line and is being programmed. In this case, similar to memory cell 410 of FIG. 4A, the memory controller may open the drain-line and the select-line of the memory cell 430. The memory controller may apply a zero-voltage (0V) to the N-Well 220. Since the memory cell 410 and the memory cell 430 are sharing a common bit-line, the same negative-voltage (−3V-5V) that is applied to the bit-line of the memory cell 410 is also applied to the bit-line of the memory cell 430.

In some embodiments, to inhibit/prevent data from being programmed to the memory cell 450, the memory controller may apply a zero-voltage to the word-line which is connected to the control gate 213 of the memory cell 450. In other words, with the applying of zero-voltage to its word-line, the memory cell 450, which is sharing a bit-line with a memory cell undergoing programming, would not be programmed.

FIG. 4D shows the overall voltage applications to a PMOS flash memory when one memory cell is being programmed, in accordance with at least some embodiments of the present disclosure. In FIG. 4D, memory cell 460 may undergoes a programming operation, memory cell 470 may be connected with the memory cell 460 via a common word-line and memory cell 480 may be connected with the memory cell 460 via a common bit-line.

In some embodiments, the voltages applied to the memory cell 460 may be shown in FIG. 4A, the voltages applied to the memory cell 470 may be shown in FIG. 4B, and the voltages applied to the memory cell 480 may be shown in FIG. 4C. In other words, the memory controller may control the programming of a specific memory cell in the memory array by applying a positive-voltage to the word-line that connecting a row of memory cells the specific memory cell is located, and may simultaneously apply a negative-voltage to the bit-line that connecting a column of memory cells the specific memory cell is located. To ensure no other memory cells in the memory array are programmed, the memory controller may apply a zero-voltage to the word-lines that connecting rows of memory cells the specific memory cell is NOT located, and may open the bit-lines that connecting columns of memory cells the specific memory cell is NOT located.

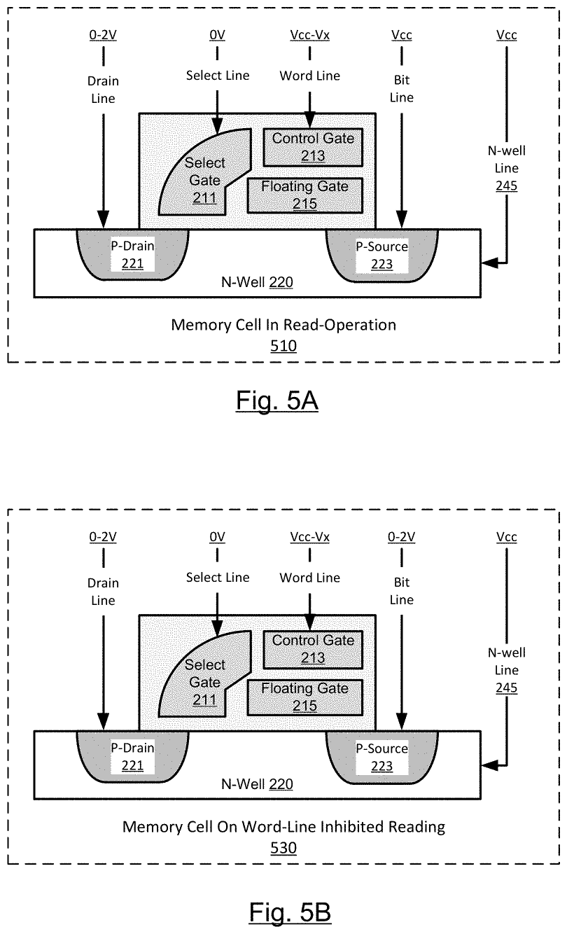

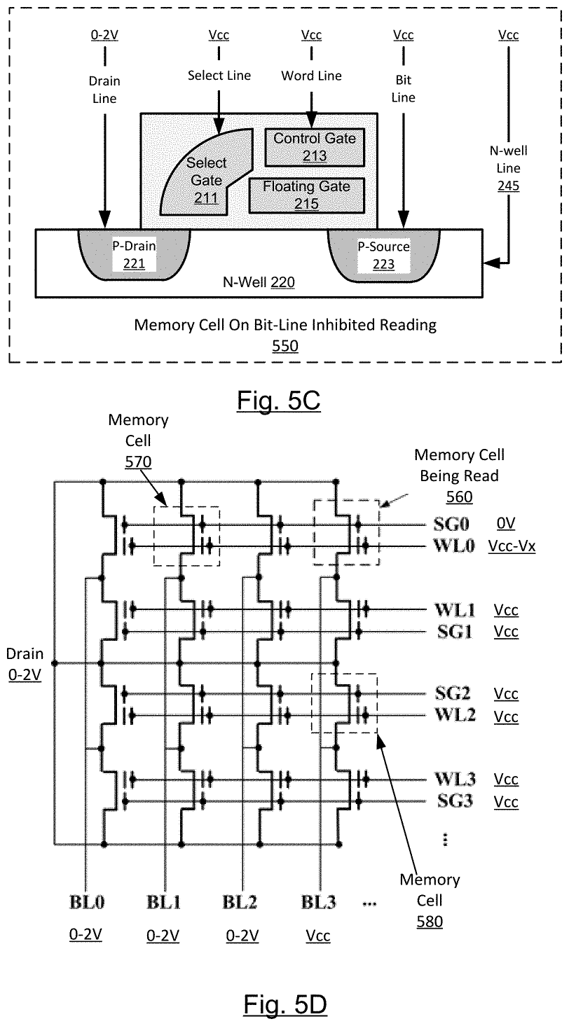

FIG. 5A shows a read-operation performed on a specific PMOS flash memory cell, in accordance with at least some embodiments of the present disclosure. In FIG. 5A, the memory cell 510 may be undergoing a read-operation to access the data stored therein. A memory controller (not shown in FIG. 5A), which may control the overall storage operations of the whole PMOS flash memory, may apply different voltages to the various lines that are connected to this specific memory cell 510. The memory controller may also facilitate the retrieving of the stored data in the memory cell 510 via the bit-line.

In some embodiments, the memory controller may apply a biased-voltage (e.g., between 0V and 2V) to the drain-line connected to the P-Drain region 221, and apply a zero-voltage (0V) to the select-line connected to the select-gate 211. The memory controller may apply an operational-voltage (Vcc) to the bit-line connected to P-Source region 223, and to the N-Well 220 via the N-well line. Further, the memory controller may apply a threshold-difference-voltage (Vcc−Vx) between Vcc and Vx to the word-line connected to the control-gate 213. The operational-voltage Vcc may be the voltage that is supplied to the whole flash memory. The Vx voltage may be the voltage difference between two threshold voltages when the flash memory device is under a turned-on (“1”) state and under a turned-off (“0”) state. The Vx voltage may ensure that the number of electrons in the floating gate is sufficient to determine whether the flash memory device is turned on or off.

In some embodiments, the arrangement as shown in FIG. 5A can prevent read disturb. As for cells adjacent to the memory cell 510 and sharing a same bit-line, since the voltage of the bit-line and the voltage of the select-line both are set to be operational-voltage (Vcc), these cells are therefore always in the OFF state, and the read operation on the selected memory cell 510 will not be affected.

FIG. 5B shows an inhibiting operation performed on a PMOS flash memory cell that is connected with the same word-line as another memory cell that is being read, in accordance with at least some embodiments of the present disclosure. In FIG. 5B, the memory cell 530 may be a memory cell inhibited from being read, when another memory cell (similar to the memory cell 510 of FIG. 5A) that is connected with memory cell 530 via the same word-line and is being read. In this case, similar to memory cell 510 of FIG. 5A, the memory controller may apply a biased-voltage (0V-2V) to the drain-line of the memory cell 530, apply a zero-voltage (0V) to the select-line, and apply an operational-voltage (Vcc) to the N-Well 220. Since the memory cell 510 and the memory cell 530 are sharing a common word-line, the same threshold-difference-voltage (Vcc−Vx) that is applied to the word-line of the memory cell 510 is also applied to the word-line of the memory cell 530.

In some embodiments, to inhibit/prevent a read-operation on the memory cell 530, the memory controller may apply the biased-voltage (0V-2V) to the bit-line that is connected to the memory cell 530. In other words, by apply the biased-voltage to its bit-line, the memory cell 530, which is sharing a word-line with a memory cell undergoing reading, would not be read or accessed.

FIG. 5C shows an inhibiting operation performed on a PMOS flash memory cell that is connected with the same bit-line as another memory cell that is being read, in accordance with at least some embodiments of the present disclosure. In FIG. 5C, the memory cell 550 may be a memory cell inhibited from being read, when another memory cell (similar to the memory cell 510 of FIG. 5A) that is connected with memory cell 550 via the same bit-line and is being read. In this case, similar to memory cell 510 of FIG. 5A, the memory controller may apply a biased-voltage (0V-2V) to the drain-line of the memory cell 550, and apply an operational-voltage (Vcc) to the N-Well 220. Since the memory cell 510 and the memory cell 550 are sharing a common bit-line, the same operational-voltage (Vcc) that is applied to the bit-line of the memory cell 510 is also applied to the bit-line of the memory cell 550.

In some embodiments, to inhibit/prevent a read-operation on the memory cell 550, the memory controller may apply an operational-voltage (Vcc) to the word-line that is connected to control-gate 213 of the memory cell 550, and to the select-gate 211 via the select-line. In comparing to a threshold-difference-voltage (Vcc−Vx) applied to the word-line of the memory cell 510, by applying the operational-voltage (Vcc) to the word-line of the memory cell 550, the memory cell 550, which is sharing a bit-line with the memory cell 510 undergoing read-operation, would not be accidentally read.

FIG. 5D shows the overall voltage applications to a PMOS flash memory when one memory cell is being read, in accordance with at least some embodiments of the present disclosure. In FIG. 5D, memory cell 560 may undergoes a read-operation, memory cell 570 may be connected with the memory cell 560 via a common word-line and memory cell 580 may be connected with the memory cell 560 via a common bit-line.

In some embodiments, the voltages applied to the memory cell 560 may be shown in FIG. 5A, the voltages applied to the memory cell 570 may be shown in FIG. 5B, and the voltages applied to the memory cell 580 may be shown in FIG. 5C. In other words, the memory controller may perform the read-operation on a specific memory cell in the memory array by applying a threshold-difference-voltage (Vcc−Vx) to the word-line that connecting a row of memory cells the specific memory cell is located, and may simultaneously apply an operational-voltage (Vcc) to the bit-line that connecting a column of memory cells the specific memory cell is located. To ensure no read-operation is performed on other memory cells in the memory array, the memory controller may apply an operational-voltage (Vcc) to the word-lines that connecting rows of memory cells the specific memory cell is NOT located, and may apply a biased-voltage (0V-2V) to the bit-lines that connecting columns of memory cells the specific memory cell is NOT located.

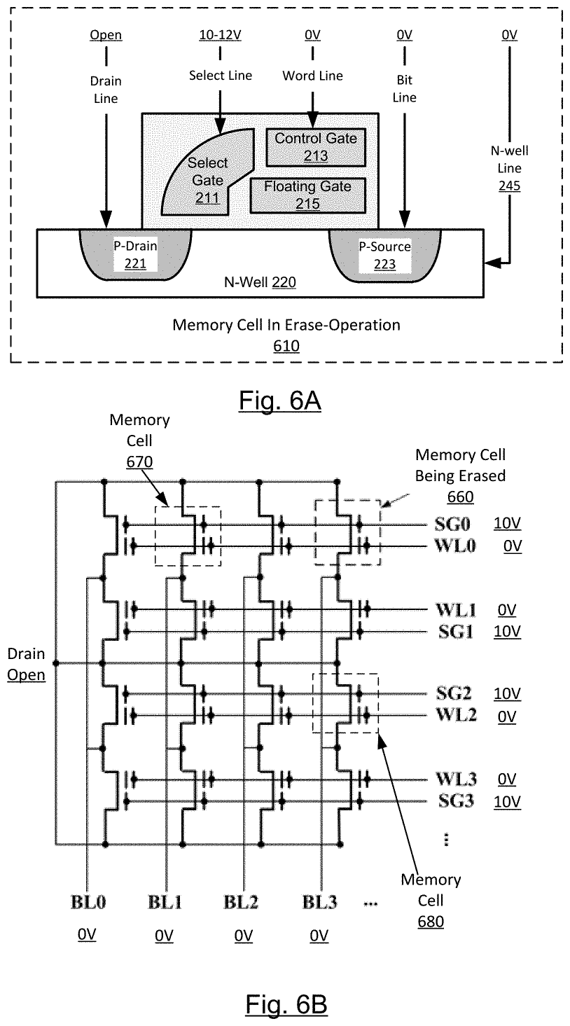

FIG. 6A shows an erase-operation performed on a specific PMOS flash memory cell, in accordance with at least some embodiments of the present disclosure. In FIG. 6A, the PMOS flash memory, which the memory cell 610 may be one of its cells, may be undergoing an erase-operation to erase the data stored therein. A memory controller (not shown in FIG. 6A), which may control the overall storage operations of the whole PMOS flash memory, may apply different voltages to the various lines that are connected to the memory cells in the PMOS flash memory.

In some embodiments, the memory controller may open the drain line connected to the P-Drain region 221, and apply a zero-voltage (e.g., substantially 0V) to the word-line connected to the control-gate 213, the bit-line connected to the P-Source region 223, and the N-Well 220 via the N-well line 245. The memory controller may apply a positive erasing-voltage (about 10V-12V) to the select-line connected to select-gate 211, in order to erase data stored in the floating gate 215.

FIG. 6B shows the overall voltage applications to a PMOS flash memory when during an erase-operation, in accordance with at least some embodiments of the present disclosure. In FIG. 6B, an erase-operation may be performed on the whole flash memory array. In this case, the memory controller may open the drain-lines connected to all the memory cells, and apply a zero-voltage to the word-lines and bit-lines that are connected to these memory cells. Further, the memory controller may apply an erase-voltage (10V-12V) to the select-lines that connected to all these memory cells.

In some embodiments, according to Gauss Law, in the overlapping region of select-gate 211 and floating-gate 215, the sharp portion of the polysilicon on the top of the floating-gate 215 may be the point of concentrated electric field intensity. Therefore, the F-N tunnelling effect is most likely to occur at this sharp portion. Due to this concentrated electric field intensity, a relatively low erase-voltage (10V-12V) applied to the select-gate 211 may be required to perform erasing operation on the memory cell.

Thus, the flash memory in the present disclosure performs writing by using the band-band hot electrons effects, and performs erasing by using the enhanced F-N tunnelling effects. The polysilicon split gate can eliminate the influence of over erasing, and reduce the voltage required by erasing and the complexity of the circuit. This flash memory structure may have the high programming efficiency of PMOS cell and the compact structure of split gate device, therefore lowing power consumption and cost.

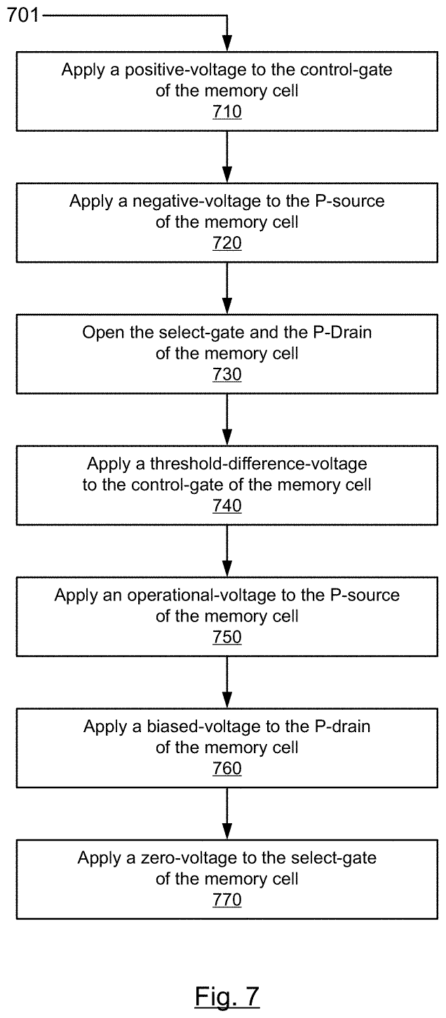

FIG. 7 shows a flow diagram of an illustrative embodiment of a process 701 for programming a P-type metal-oxide-semiconductor (PMOS) flash memory cell as described herein. The described process 701 sets forth various functional blocks or actions that may be described as processing steps, functional operations, events, and/or acts, as illustrated by one or more of blocks in FIG. 7. The various blocks may be performed by hardware, software, firmware, or a combination thereof.

Those skilled, in the art in light of the present disclosure, will recognize that numerous alternatives to the blocks shown in FIG. 7 may be practiced in various implementations. For this and other processes and methods disclosed herein, the functions performed in the described processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments. Also, one or more of the outlined steps and operations may be performed in parallel.

A PMOS flash memory cell may include a floating-gate, a control-gate, a select-gate, a P-source, and a P-drain. The process 701 for programming and reading the memory cell may begin at block 710. At block 710, a memory controller may program the memory cell by applying a positive-voltage to the control-gate of the memory cell via a word-line that connected to the memory cell.

At block 720, the memory cell may be programmed by applying a negative-voltage to the P-source of the memory cell via a bit-line. At block 730, the memory cell may be programmed by opening the select-gate and the P-Drain of the memory cell via the select-line and drain-line connected therewith respectively.

At block 740, the memory control may further read the memory cell by applying a threshold-difference-voltage to the control-gate via the word-line. At block 750, the memory controller may further read the memory cell by applying an operational-voltage to the P-source via the bit-line. At block 760, the memory cell may be further read by applying a biased-voltage to the P-drain via the drain-line. At block 770, the memory cell may further be read by applying a zero-voltage to the select-gate via a select-line.

In some embodiments, a semiconductor fabrication system may be configured to perform some or all of the above fabrication operations and to construct one or more PMOS memory cells in a wafer. The semiconductor fabrication system may include, without limitation, oxidation equipment, deposition equipment, lithographic equipment, cleaning equipment, annealing equipment, and dicing equipment. A wafer, which may be a thin slice of semiconductor material (e.g., silicon crystal), may be processed by equipment from the above system one or more times based on operation routes, product's specifications, and manufacturing recipes.

In some embodiments, the oxidization equipment may be configured to perform one or more of thermal oxidation, wet anodization, chemical vapor deposition (CVD), and/or plasma anodization or oxidation operations. The oxidation equipment may be configured to oxidize the surface of the wafer in order to form a layer of silicon dioxide. The deposition equipment may be configured to deposit a layer of specific material over the wafer. In some embodiments, the deposition equipment may deposit an oxide layer or a N-Well above a surface of the wafer.

In some embodiments, the lithographic equipment may be configured to perform wet-etching, dry-etching, or plasma-etching operations in order to construct and/or remove portions of semiconductor layers. The cleaning equipment may be configured to rinse and clean the surface of semiconductor components after the deposition, etching, and/or dicing operations. The annealing equipment may be configured to anneal the semiconductor components by applying high-temperature heat toward the wafer. The dicing equipment may be configured to dice a fabricated silicon wafer into a diced wafer. Afterward, the silicon wafer may be cut/diced into a plurality of wafer segments, each of which may be used to construct a finished product. The wafer segments may then be packaged into a final product, e.g., a PMOS flash memory.

Thus, methods and systems for constructing a PMOS memory cell have been described. Although the present disclosure has been described with reference to specific example embodiments, it will be recognized that the disclosure is not limited to the embodiments described, but can be practiced with modification and alteration within the spirit and scope of the appended claims. Accordingly, the specification and drawings are to be regarded in an illustrative sense rather than a restrictive sense.

There is little distinction left between hardware and software implementations of aspects of systems; the use of hardware or software is generally (but not always, in that in certain contexts the choice between hardware and software can become significant) a design choice representing cost vs. efficiency tradeoffs. There are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In some embodiments, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Versatile Disk (DVD), a digital tape, a computer memory; and a transmission type medium such as a digital and/or an analog communication medium (e.g., a fiber optic cable, a waveguide, a wired communications link, a wireless communication link).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or coupled with, different other components. It is to be understood that such depicted architectures are merely examples and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to”). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

I claim:

1. A P-type metal-oxide-semiconductor (PMOS) flash memory cell in a semiconductor substrate, comprising:
a P-substrate layer formed above the semiconductor substrate;
a N-well formed in the P-substrate layer;
a floating-gate formed above the N-well;
a control-gate formed above the floating-gate;
a select-gate formed above the N-well and extending over at least a portion over the floating-gate;
a P-source formed in the N-well, wherein the P-source is formed adjacent to the floating-gate; and
a P-drain formed in the N-well, wherein the P-drain is formed adjacent to the select-gate.

2. The PMOS flash memory cell of claim 1, further comprising:
a word-line connected with the control-gate for applying a voltage to the control-gate;
a select-line connected with the select-gate for applying a voltage to the select-gate; and
a bit-line connected with the P-source for applying a voltage to the P-source.

3. The PMOS flash memory cell of claim 1, further comprising:
a tunnel oxide layer formed on the N-well, wherein the tunnel oxide layer is above the N-well and below the floating-gate.

4. The PMOS flash memory cell of claim 1, wherein the PMOS flash memory cell is programmed by
applying a positive-voltage to the control-gate,
applying a negative-voltage to the P-source, and
opening the select-gate and the P-drain.

5. The PMOS flash memory cell of claim 4, wherein the PMOS flash memory cell is deemed a first cell,
the first cell is coupled with a second cell via a corresponding word-line, and
when the first cell is being programmed, the second cell is inhibited from being programmed by opening the second cell's P-source.

6. The PMOS flash memory cell of claim 4, wherein the PMOS flash memory cell is deemed a first cell,
the first cell is coupled with a second cell via a corresponding bit-line, and
when the first cell is being programmed, the second cell is inhibited from being programmed by applying a zero-voltage to the second cell's control-gate.

7. The PMOS flash memory cell of claim 1, wherein the PMOS flash memory cell is being read by
applying a threshold-difference-voltage to the control-gate,
applying an operational-voltage to the P-source,
applying a biased-voltage to the P-drain, and
applying a zero-voltage to the select-gate.

8. The PMOS flash memory cell of claim 7, wherein the PMOS flash memory cell is deemed a first cell,
the first cell is coupled with a second cell via a corresponding word-line, and
when the first cell is being read, the second cell is inhibited from being read by applying the biased-voltage to the second cell's P-source.

9. The PMOS flash memory cell of claim 7, wherein the PMOS flash memory cell is deemed a first cell,
the first cell is coupled with a second cell via a corresponding bit-line, and
when the first cell is being read, the second cell is inhibited from being read by applying the operational-voltage to the second cell's select-gate and the second cell's control-gate.

10. The PMOS flash memory cell of claim 1, wherein the PMOS flash memory cell is erased along with other memory cells in a flash memory by
applying an erase-voltage to the select-gate,
applying a zero-voltage to the control-gate and the P-source, and
opening the P-drain.

11. A P-type metal-oxide-semiconductor (PMOS) flash memory, comprising:
a plurality of cells including a first cell, a second cell, a third cell, and a fourth cell, wherein each of the plurality of cells correspondingly comprises a floating-gate, a control-gate, a select-gate, a P-source, and a P-drain;
a plurality of word-lines including a first word-line connecting the first cell and the second cell and a second word-line connecting the third cell and the fourth cell, wherein each of the plurality of word-lines connects with and applies a voltage to the corresponding control-gate of the plurality of cells;
a plurality of bit-lines including a first bit-line connecting the first cell and the third cell and a second bit-line connecting the second cell and the fourth cell, wherein each of the plurality of bit-lines connects with and applies a voltage to the corresponding P-sources of the plurality of cells;
a plurality of select-lines including a first select-line connecting the first cell and the second cell and a second select-line connecting the third cell and the fourth cell, wherein each of the plurality of select-lines connects with and applies a voltage to the corresponding select-gate of the plurality of cells; and
a plurality of drain-lines for connecting with the corresponding P-drains of the plurality of cells.

12. The PMOS flash memory of claim 11, wherein the first cell is programmed by:
applying a positive-voltage to the first word-line,
applying a negative-voltage to the first bit-line, and
opening the first select-line and the drain lines.

13. The PMOS flash memory of claim 12, wherein the second cell is inhibited from being programmed by opening the second bit-line.

14. The PMOS flash memory of claim 12, wherein the third cell is inhibited from being programmed by applying a zero-voltage to the second word-line.

15. The PMOS flash memory of claim 11, wherein the first cell is being read by:
applying a threshold-difference-voltage to the first word-line,
applying an operational-voltage to the first bit-line,
applying a biased-voltage to the plurality of drain-lines, and
applying a zero-voltage to the first select-line.

16. The PMOS flash memory of claim 15, wherein the second cell is inhibited from being read by:
applying the biased-voltage to the second bit-line.

17. The PMOS flash memory of claim 15, wherein the third cell is inhibited from being read by:
applying the operational-voltage to the second word-line and to the second select-line.

18. The PMOS flash memory of claim 11, wherein the flash memory is being erased by:
applying a zero-voltage to the plurality of word-lines,
applying a zero-voltage to the plurality of bit-lines,
applying an erase-voltage to the plurality of select-lines, and
opening the plurality of drain-lines.

19. A method for programming a P-type metal-oxide-semiconductor (PMOS) flash memory cell, the PMOS flash memory cell comprises a floating-gate, a control-gate, a select-gate, a P-source, and a P-drain, the method comprising:
applying a positive-voltage to the control-gate;
applying a negative-voltage to the P-source; and
opening the select-gate and the p-drain.

20. The method as recited in claim 19, wherein the method further comprises reading the PMOS flash cell by
applying a threshold-difference-voltage to the control-gate,
applying an operational-voltage to the P-source,
applying a biased-voltage to the P-drain, and
applying a zero-voltage to the select-gate.
